(19) United States
(12) Patent Application Publication
(10) Pub. No.: US 2013/0033807 A1
(43) Pub. Date: Feb. 7, 2013

(54) DOCKING SYSTEMS WITH A MOUNTING ARM AND RETRACTABLE KEYBOARD FOR ELECTRONIC DEVICES

(71) Applicant: Justin C. Kim, Great Neck, NY (US)

(72) Inventor: Justin C. Kim, Great Neck, NY (US)

(21) Appl. No.: 13/565,206

(22) Filed: Aug. 2, 2012

Related U.S. Application Data
(60) Provisional application No. 61/515,489, filed on Aug. 5, 2011.

(51) Int. Cl. H05K 5/00

(52) U.S. Cl. 361/679.01

(57) ABSTRACT

Docking systems (10) for electronic devices (11) include a housing (39), (44), and an arm (16) mounted on the housing (39), (44). The arm (16) is configured to hold the electronic device (11), and to articulate in relation to the housing (39), (44) so that a viewing angle and a viewing orientation of a display of the electronic device (11) can be adjusted. Embodiments can include a speaker (49) mounted on the housing (39), (44), and/or a keyboard (46). The keyboard (46) can be mounted on the housing (39), (44), and can be configured to move between a stowed position wherein substantially all the keyboard (46) is located within the housing (39), (44), and a deployed position wherein substantially all of the keyboard (46) is located outside of the housing (39), (44).

### CROSS-REFERENCE TO RELATED APPLICATIONS

This application claims the benefit under 35 U.S.C. §119(e) of U.S. Provisional Application No. 61/515,489, filed Aug. 5, 2011, the contents of which are incorporated by reference herein in their entirety.

### BACKGROUND OF THE INVENTION

1. Statement of the Technical Field

The inventive arrangements relate to docking systems that accommodate electronic devices such as tablet computing device cellular telephones, portable media players, etc.

2. Description of Related Art

Portable electronic devices such as tablet computers, smart phones, portable media players, etc. are in widespread use. It is often desired to mate such devices with a docking station for purposes such as charging, uploading and downloading data, providing an audio feed to a external speakers, inputting data using an external keyboard, operating the device on a hands-free basis, etc. Due to the disparate shapes and sizes of tablet computers, smart phones, portable media players, etc., docking stations are typically limited to use with one particular type of device. Moreover, it can be difficult to provide multiple features in a docking station, e.g., high-fidelity audio and a keyboard, while keeping its dimensional footprint small enough to permit the docking station to conveniently fit within the confines of a desk top or other limited space. Also, because docking stations typically do not permit the relative position of the electronic device to be varied once it is docked, it may be difficult for some users to view the display of the electronic device at an optimal or otherwise acceptable angle and orientation.

### SUMMARY OF THE INVENTION

Embodiments of docking systems are provided for electronic devices having displays. The embodiments include a housing, and a keyboard mounted on the housing and configured to move between a stowed position wherein substantially all the keyboard is located within the housing, and a deployed position wherein substantially all of the keyboard is located outside of the housing. The embodiments also include a speaker mounted on the housing, and an arm configured to hold the electronic device. The arm is mounted on the housing so that the arm is capable of rotating about a first axis in relation to the housing to facilitate adjustment of a viewing angle of the display while the electronic device is held by the arm.

Other embodiments of docking systems for electronic devices include a housing, and an arm configured to hold the electronic device. The arm has a first portion, a second portion, and a third portion. An end of the second portion is pivotally coupled to the housing so that the second portion is capable of rotating in relation to the housing about a first axis extending in a first direction substantially perpendicular to a lengthwise direction of the second portion. The first portion is mounted on the second portion so that the first portion is capable of rotating in relation to the second portion about a second axis extending in a second direction substantially perpendicular to the lengthwise direction of the second portion. The third portion is configured to be removably mounted on the first portion and to securely grasp the electronic device. The embodiments further include a connector mounted on the first portion of the arm and configured to mate with a dock connector port of the electronic device.

Further embodiments of docking systems are provided for electronic devices having displays. The embodiments include a housing, and a keyboard mounted on the housing and configured to move between a stowed position wherein substantially all the keyboard is located within the housing, and a deployed position wherein substantially all of the keyboard is located outside of the housing. The embodiments also include a speaker mounted on the housing, and an arm mounted on the housing. The arm is configured to hold the electronic device and to articulate in relation to the housing so that a viewing angle and a viewing orientation of the display can be adjusted while the electronic device is held by the arm. The embodiments further include a connector mounted on the arm and communicatively coupled to the keyboard and the speaker. The connector is configured to mate with a dock connector port of the electronic device.

### BRIEF DESCRIPTION OF THE DRAWINGS

Embodiments will be described with reference to the following drawing figures, in which like numerals represent like items throughout the figures, and in which:

FIG. 1A is a top perspective view of a docking system for an electronic device, with a keyboard of the system in a retracted position, and a mounting arm of the system in a lower position;

FIG. 1B is a top perspective view of the docking system shown in FIG. 1A, with the keyboard in the retracted position, and the mounting arm in the lower position and rotated ninety-degrees from the orientation depicted in FIG. 1A;

FIG. 2 is a top perspective view of the docking system shown in FIGS. 1A and 1B, with the keyboard in a deployed position and the mounting arm in the position and orientation depicted in FIG. 1A;

FIG. 3 is a top view of the docking system shown in FIGS. 1-2, with the keyboard in the deployed position and the mounting arm in the position and orientation depicted in FIG. 1A;

FIG. 4 is a front view of the docking system shown in FIGS. 1-3, with the keyboard in the retracted position and the mounting arm in the lower position;

FIG. 5A is a side view of the docking system shown in FIGS. 1-4, with the keyboard in the retracted position and the mounting arm in an upper position;

FIG. 5B is a side view of the docking system shown in FIGS. 1-5A, with the keyboard in the retracted position and the mounting arm in the position and orientation depicted in FIG. 1A;

FIG. 6 is a partially-exploded, top perspective view of the docking system shown in FIGS. 1-5B, with the keyboard in the retracted position and the mounting arm in the position and orientation depicted in FIG. 1A, and depicting in phantom an electronic device mounted on the system;

FIG. 7 is another partially-exploded, top perspective view of the docking system shown in FIGS. 1-6, depicting various internal components of the retractable keyboard assembly;

FIG. 8 is a top perspective view of the keyboard of the docking system shown in FIGS. 1-7, mounted in a lower portion of a body of a keyboard module of the system to form a keyboard assembly; other components of the docking system are not shown in this view;

FIG. 9 is a top perspective view of the keyboard assembly of the docking system shown in FIGS. 1-8, with the keyboard in the deployed position;

FIG. 10A is a top perspective view of the keyboard of the docking system shown in FIGS. 1-9, depicting details of a roller assembly;

FIG. 10B is a magnified detailed exploded view of the area designated “A” in FIG. 10A;

FIG. 11 is an isometric view of a lower portion of a body of the keyboard module of the docking system shown in FIGS. 1-10B, depicting components essential for a retracting function of the keyboard assembly;

FIG. 12 is a top view of an alternative holder for use on a mounting arm of the docking system shown in FIGS. 1-11, to accommodate electronic devices having different external dimensions; and

FIG. 13 is a block diagram depicting various electronic components of the system shown in FIGS. 1-12.

### DETAILED DESCRIPTION

Docking systems are provided for use with electronic devices including, but not limited to the APPLE IPAD tablet computing device, the APPLE IPHONE cellular telephone, the APPLE IPOD portable media player, and other types of electronic devices. The docking systems hold and support the electronic devices, and can include one or more internal speakers that provide an output based on audio signals generated by the electronic device. The docking systems can include a keyboard module that enables a user to interface with the electronic device. The keyboard module can include a keyboard assembly that incorporates, for example, a full-size or mini keyboard assembly, a rubber keypad assembly, a touch screen, or a virtual keyboard assembly that is connected to the electronic device via wired or wireless means. The keyboard assembly can be fully retractable, and can be hidden within a body of the keyboard module when not in use so that the docking systems have a relatively compact dimensional footprint.

The docking systems can also include a mounting arm that can be configured by the user to accommodate electronic devices having different external dimensions. The position of the mounting arm can be made adjustable, to facilitate optimization of the viewing angle of the screen of the electronic device. The term “viewing angle,’ as used in the specification and claims, refers to the angle between the line of sight of the user and the plane of the viewing surface of the display of the electronic device. The mounting arm can also be configured so that the orientation of the electronic device can be adjusted for viewing in both portrait and landscape formats. The term “portrait,” as used in the specification and claims, refers to an orientation of the display in which the lengthwise direction of the display is oriented vertically in relation to the user. The term “landscape,” as used in the specification and claims, refers to an orientation of the display in which the lengthwise direction of the display is oriented horizontally in relation to the user. The mounting arm can include a connector that facilitates communication between the electronic device and the speaker system, keyboard, and other electronic components of the docking system.

The docking systems can be used on a desk top, bedside table, or other location. Applications can be downloaded onto the electronic device to facilitate use of the docking system and the electronic device as an internet radio, an alarm clock with large-clock display, a means for displaying the local weather forecast and conditions, etc.

The invention is described with reference to the attached figures. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operation are not shown in detail to avoid obscuring the invention. The invention is not limited by the illustrated ordering of acts or events, as some acts may occur in different orders and/or concurrently with other acts or events. Furthermore, not all illustrated acts or events are required to implement a methodology in accordance with the invention.

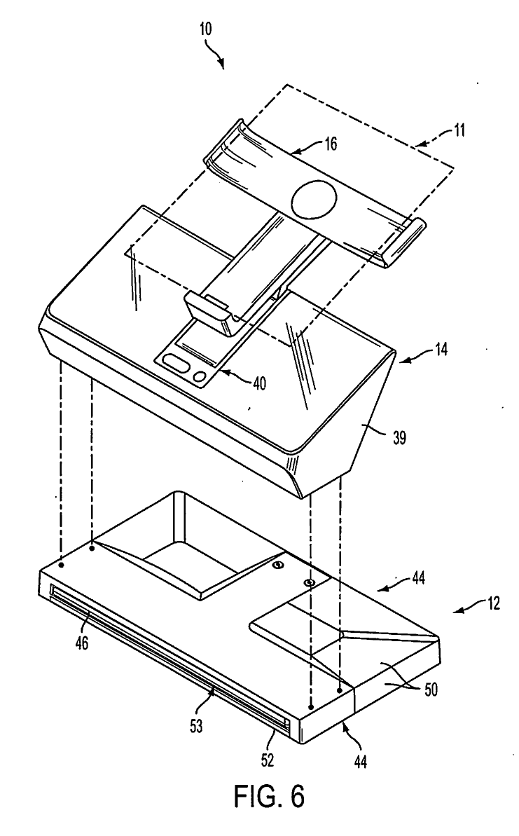

A docking system 10 is provided for use with electronic devices including, but not limited to the APPLE IPAD tablet computing device, the APPLE IPHONE cellular telephone, the APPLE IPOD portable media player, and other types of electronic devices. For the purposes of this description, the docking system 10 is described as being used with an electronic device 11, depicted in phantom in FIG. 6.

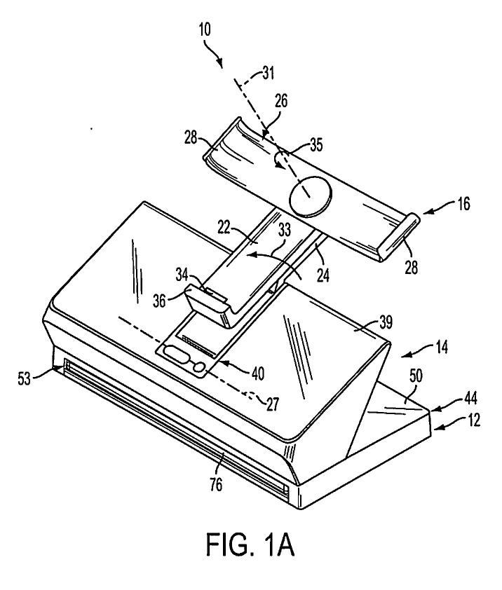

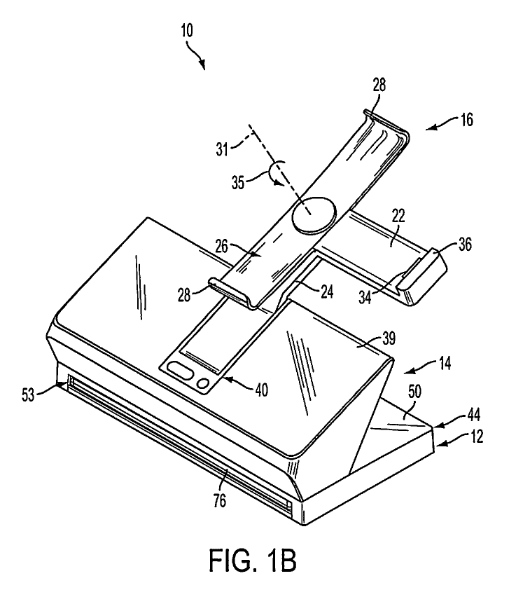

The docking system 10 comprises a keyboard module 12, a speaker module 14 mounted on the keyboard module 12, and a mounting arm 16 mounted on the speaker module 14. The mounting arm 16 supports the electronic device 11. The mounting arm 16 can be configured by the user to accommodate electronic devices 11 of different physical dimensions. For example, the mounting arm 16 is depicted in FIGS. 1-7 in a configuration suitable for supporting a tablet computing device such as the APPLE IPAD.

The mounting arm 16 can include a first portion 22, and a second portion 24. The first and second portions 22, 24 can be formed from a durable, impact-resistant material such as high-impact plastic. The first and second portion 22, 24 can be formed from other types of materials, including but not limited to metallic materials, in the alternative.

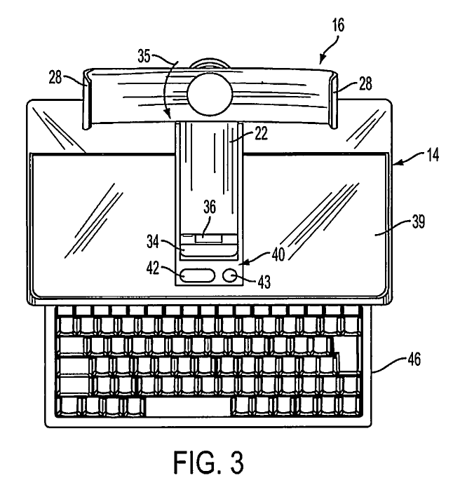

The first portion 22 can be coupled to the second portion 24 by a pin or other suitable means, so that the first portion 22 can rotate in relation to the second portion 24 as denoted by the arrow 35 in FIGS. 1A, 1B, and 3. As can be seen, for example, in FIGS. 1A, 1B, and 3, the first portion 22 rotates about an axis that is substantially perpendicular to a lengthwise direction of the second portion 24. The axis of rotation of the first portion 32 is denoted in FIG. 1 by the reference character 31. This feature permits the user to alter the viewing orientation of the electronic device 11 between portrait and landscape formats.

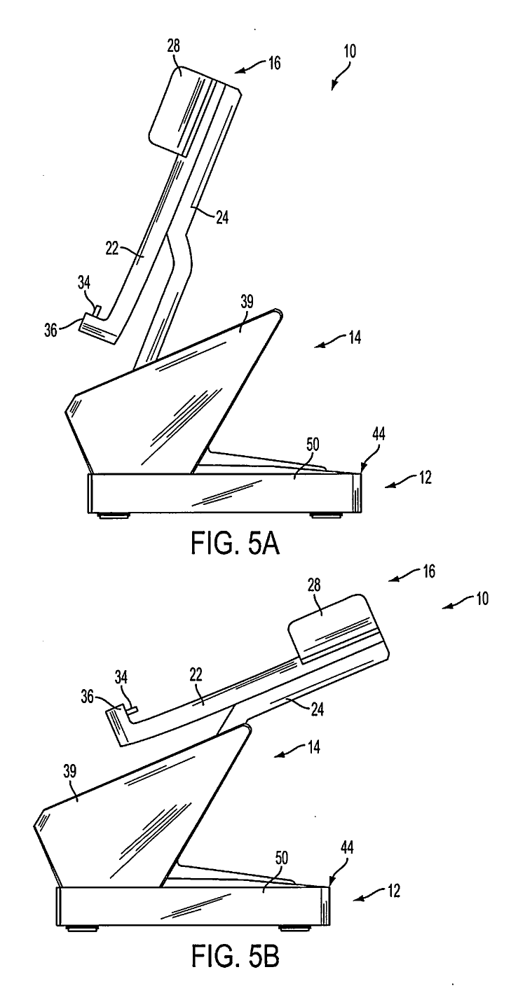

A first or lower end of the second portion 24 can be mechanically coupled to a housing 39 of the speaker module 14 by way of a hinge (not shown) that permits the second portion 24 and the remainder of the mounting arm 16 to pivot about a horizontally-oriented axis, in the direction denoted by the arrow 33 in FIG. 1A. The axis of rotation of the second portion 24 is denoted in FIG. 1A by the reference character 27. The hinge can be a detent hinge that permits the second portion 24, and the remainder of the mounting arm 16, to remain at any of a number of predetermined rotational positions, i.e., tilt angles, throughout the range of motion of the hinge. For example, the user can rotate the mounting arm 16 between a lower position depicted in FIGS. 1A-4 and 5B, and an upper position depicted in FIG. 5A. This feature allows the user to adjust the viewing angle of the screen of the electronic device 11 so as to position the screen at an optimal viewing angle for that particular user. The second portion 24 can be coupled to the housing 39 using suitable means other than a detent hinge in alternative embodiments.

The mounting arm 16, when configured to support a tablet computing device such as the APPLE IPAD, can include an elongated holder in the form of a third portion 26. The third portion 26 can be removably mounted on an upper end of the first portion 22, i.e., the third portion 26 can be removed from and reinstalled on the first portion 22 by the user. The third portion 26 can have a lip (not shown) formed on a rear surface thereof. The lip can securely engage the first portion 22 via a groove (also not shown) formed in the first portion 22. The third portion 26 can be secured to the first portion 22 using fasteners or other suitable means in the alternative.

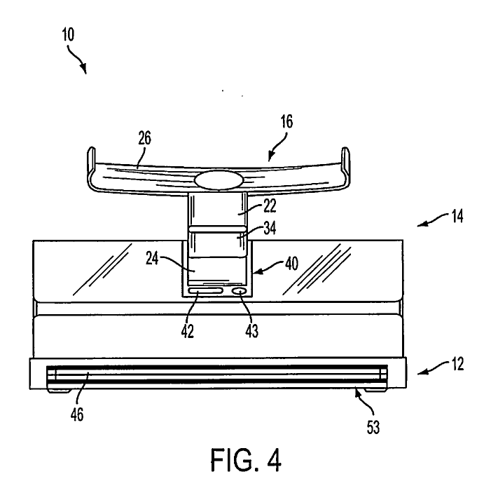

The third portion 26 can includes two lips 28 located at opposing ends thereof as shown FIGS. 1-7, to help to restrain the electronic device 11 on the mounting arm 16. The lips 28 can be integrally formed with the remainder of the third portion 26 in alternative embodiments. The third portion 26 is configured so that the lips 28 firmly grasp the electronic device 11 when the electronic device 11 is placed on the mounting arm 16, thus helping to secure the electronic device 11 on the mounting arm 16. Relatively soft pads or like features can be attached to the inwardly-facing surface of each lip 28 in alternative embodiments, to cushion and prevent scratching of the electronic device 11. In other alternative embodiments, the lips 28 can be mounted on the remainder of the third portion 26 so the lateral position of each lip 28 i.e., the left-right positions from the perspective of FIG. 4, can be adjusted to accommodate electronic devices 11 of different widths.

The first portion 22 can include a lip 34 at or near a lower end thereof as shown, for example, in FIGS. 1-7. The lip 34 helps to support the electronic device 11 when the electronic device 11 is in a portrait orientation. A connector 36 can be mounted on the lip 34. The connector 36 can be configured to mate with a dock connector port on the electronic device 11, to communicatively couple the electronic device 11 to the docking system 10.

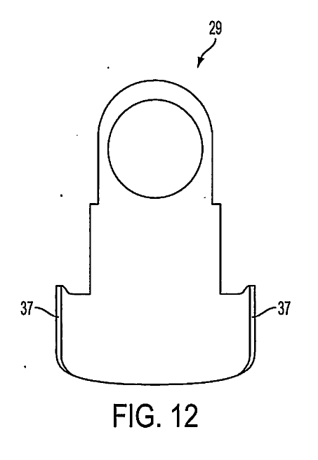

The mounting arm 16, when configured to support a cellular telephone such as the APPLE IPHONE or a portable media player such as the APPLE IPAD, can be equipped with a relatively small holder in the form of a fourth portion 29 that accommodates electronic devices of that size. The fourth portion 29 is shown in FIG. 12. The forth portion 29 includes lips 37 that grasp the electronic device 11 in a manner similar to the lips 28 of the third portion 26. The fourth portion 29 can be removably mounted on the first portion 22. The fourth portion 29 can have a lip (not shown) formed on a rear surface thereof that securely engages the first portion 22 via the above-noted groove formed in the first portion 22. The fourth portion 29 can be secured to the first portion 22 using fasteners or other suitable means in the alternative.

The fourth portion 29 and the third portion 26 thus are interchangeable to permit the system 10 to accommodate differently-sized electronic devices 11. Moreover, the system 10 can include additional portions for the mounting arm 16 that can be used in lieu of the third and fourth portions 26, 29 to permit the mounting arm 16 to accommodate electronic devices other than tablet computing devices and cellular telephones.

The housing 39 of the speaker module 14 can be formed from a durable, impact-resistant material such as high-impact plastic. The housing 39 can be formed from other types of materials, including but not limited to metallic materials, in the alternative.

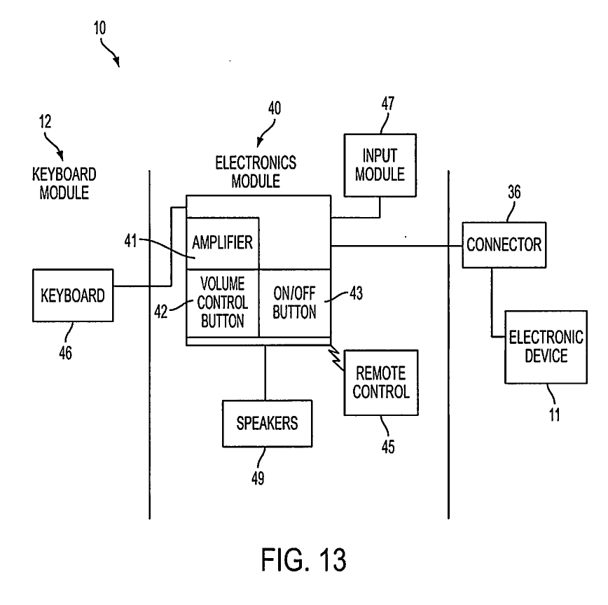

One or more speakers 49, depicted schematically in FIG. 13, can be mounted inside the housing 39. Grills or other suitable means can be disposed on the housing 39 to provide an acoustical path for the output of the speakers 49.

The housing 39 can be shaped so as to help optimize the acoustical performance of the speakers 49. For example, the interior cavity of the housing 39, in which the speakers 49 are located, can be shaped so as to amplify the low-frequency response of the speakers 49 so that the system 10 produces bass levels sufficient for a particular room size.

The speaker module 14 can also include an electronics module 40 mounted on the housing 39. The electronics module 40 is visible in part, for example, in FIGS. 1-4, 6, and 7, and is depicted in the form of a block diagram in FIG. 13. The electronics module 40 is communicatively coupled to the connector 36 and the speakers 49. The electronics module 40 can include an amplifier 41, and a volume control button 42 communicatively coupled to the speakers 49 as shown in FIG. 13. The amplifier 41 generates an output that drives the speakers 49, based on an input generated by the electronic device 11 and transmitted to the amplifier 41 via the dock connector port of the electronic device 11 and the connector 36. The volume control button 42 facilitates control of the volume of the speakers 49 by the user.

The electronics module 40 can also include an on/off button 43 that permits the user to turn the electronic device 11 on and off. The electronics module 40 of alternative embodiments can be equipped with additional buttons that facilitate other user inputs to the electronic device 11, such as play, pause, forward, reverse, mute, enter, menu, up, down, etc.

The system 10 can include a wireless remote control 45, shown in FIG. 13, that communicates with the electronics module 40 to permit the user to enter the following inputs on a remote basis: on/off, volume, play, pause, forward, reverse, mute, enter, menu, up, down, etc. The electronics module 40 can also be equipped with circuitry (not shown) to charge the battery of the electronic device 11 via the connector 36.

The speaker module 14 can also include an input module 47 mounted on the housing 39 and communicatively coupled to the electronics module 40. The input module 47 is depicted in FIG. 13. The input module 47 can include, for example, a synchronization port; an auxiliary-input port that permits an MP3 player, smart phone, or other device to communicate with the electronics module 40; a port that receives electric power, such as 12-volt DC power or 120-volt AC power from a source such as a wall outlet; a high-definition multimedia interface (HDMI) port that facilitates display of the screen image of the electronic device 11 on, for example, a large-screen television, etc. Alternative embodiments of the system 10 can be configured without the speaker module 14.

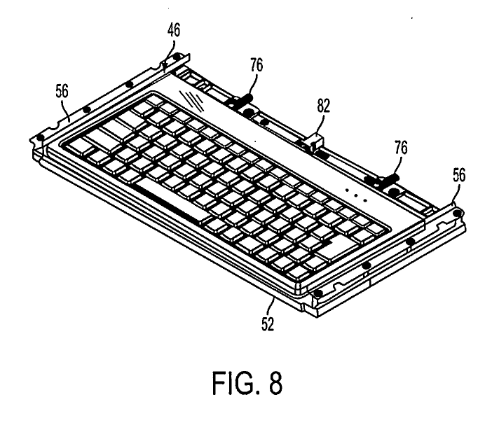

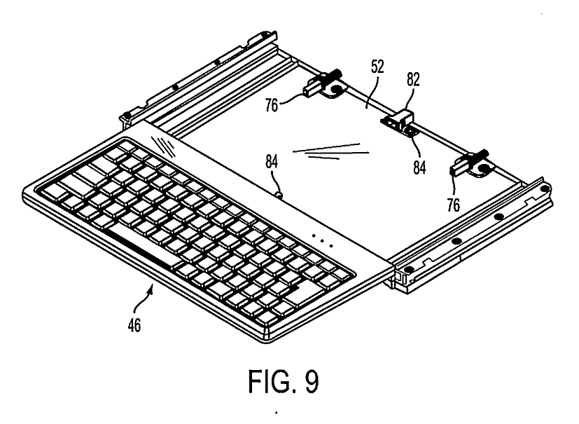

The keyboard module 12 can include a housing 44, and the keyboard 46. The keyboard 46 is movably disposed within the housing 44. The housing 44 comprises an upper portion 50 and a lower portion 52. The keyboard 46 is mounted for movement on the lower portion 52, and the keyboard 46 and the lower portion 52 together form a keyboard assembly as shown in FIGS. 8 and 9. The upper and lower portions 50, 52 define an opening 53 in the housing 44, as shown for example in FIGS. 1A, 1B, 2, and 4. The opening 53 facilitates movement of the keyboard 46 into and out of the housing 44. The upper and lower portions 50, 52 can be formed from a durable, impact-resistant material such as high-impact plastic. The upper and lower portions 50, 52 can be formed from other types of materials, including but not limited to metallic materials, in the alternative. The term “keyboard,” as used throughout the specification and claims, is intended to encompass all types of keyed input device, including but not limited to full-size and mini keyboards, rubber keypad assemblies, touch screens, virtual keyboards, etc.

Although the housing 44 of the keyboard module 12 and the housing 39 of the speaker module 14 are referred to herein as separate housings, the housing 44 and the housing 39 can be considered portions of an overall housing of the system 10. Moreover, the housing 44 and the housing 39 can be unitarily formed in alterative embodiments.

The keyboard 46 can be communicatively coupled to the electronics module 40 via a wired or wireless means, and can communicate with the electronic device 11 via the connector 36 and the dock connector port on the electronic device 11. The connection between the keyboard 46 and the connector 36 can be provided by a direct wired connection between the keyboard and the connector 36, or can be facilitated by the electronics module 40. If facilitated by electronics module 40, the electronics module 40 can provide suitable anti key bounce, buffering and/or interface circuitry to permit the electronic device 11 to properly recognize inputs asserted by a user with the keyboard 46. In alternative embodiments, the keyboard 46 can be configured to communicate directly with the electronic device 11 via a suitable wireless communication means, such as a wireless transceiver configured with a BLUETOOTH communications protocol. In such an arrangement, a wireless transceiver can be integrated into the keyboard 46.

The electronics module 40 is configured to transmit and receive analog and digital information and to receive power on a simultaneous basis. Thus, the speakers 49 can be operated while the keyboard 46 is providing inputs to the electronic device 11 wirelessly, or on a wired basis through the connector 36, and while the electronic device 11 is being charged via the electronics module 11 and the connector 36.

The housing 39 of the speaker module 14 can be mounted on the upper portion 50 of the housing 44 of the keyboard module 12 by a suitable means such as fasteners (not shown). The fasteners can be disposed in through holes 54 that extend through the upper portion 50, and engage tabs (not shown) on the housing 39 of the speaker module 14.

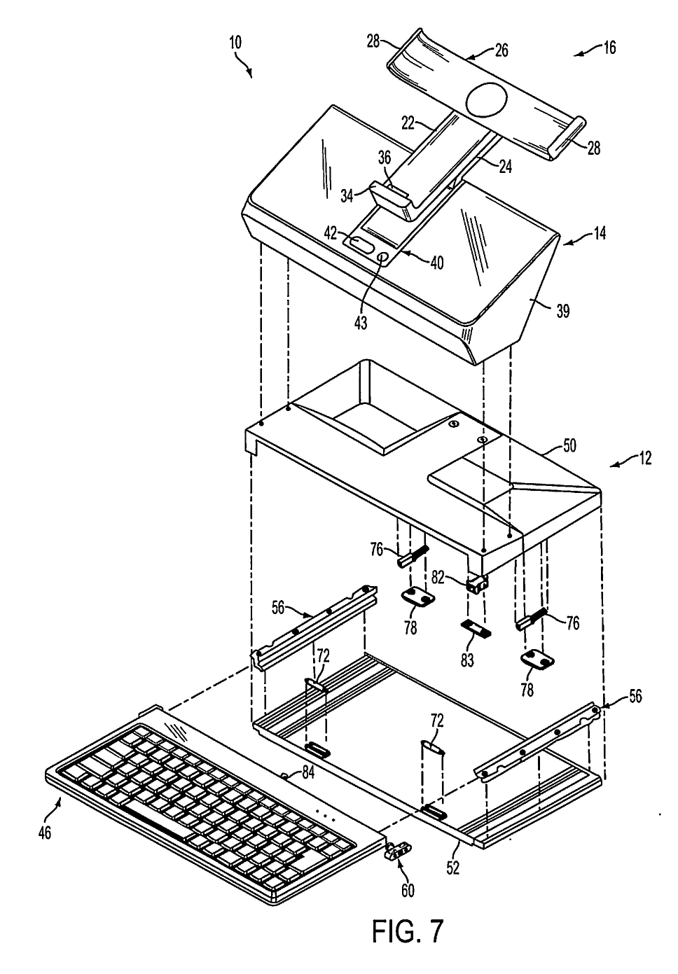

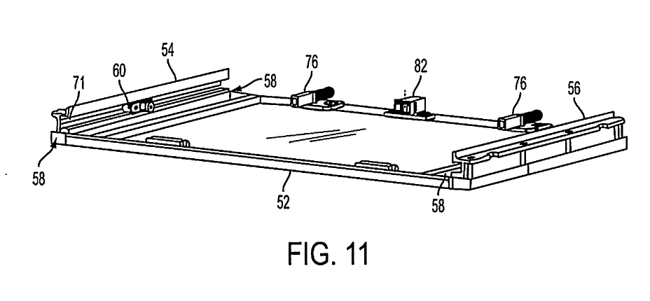

The keyboard module 12 can include two rails 56. The rails 56 can be mounted on the lower portion 52 of the housing 44 as shown in FIGS. 7 and 11, using a suitable means such as fasteners. Each rail 56 is mounted proximate a respective end or side of the lower portion 52.

The rails 56 engage the keyboard 46 via roller assemblies 60 mounted on the keyboard 46, to facilitate movement of the keyboard 46 into and out of the housing 44. Each rail 56 has a groove 58 formed therein as shown in FIG. 11. The groove 58 of each rail 56 accommodates one of the roller assemblies 60.

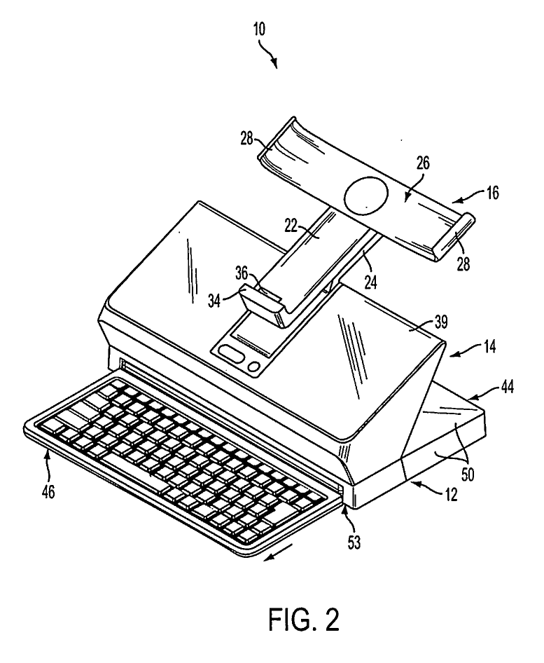

The roller assemblies 60 are mounted on opposite sides of the keyboard 46, proximate the rearward end thereof. The roller assemblies 60 each slide within their associated groove 58, to restrain and guide the keyboard 46 as the keyboard 46 translates between a retracted or stowed position, and a deployed position. Substantially all of the keyboard 46 is disposed within the housing 44 when the keyboard 46 is in its retracted position, as shown for example in FIGS. 1A and 1B. Substantially all of the keyboard 46 is positioned in front of the housing 44 when the keyboard 46 is in its deployed position, as shown for example in FIG. 2, to facilitate use of the keyboard 46.

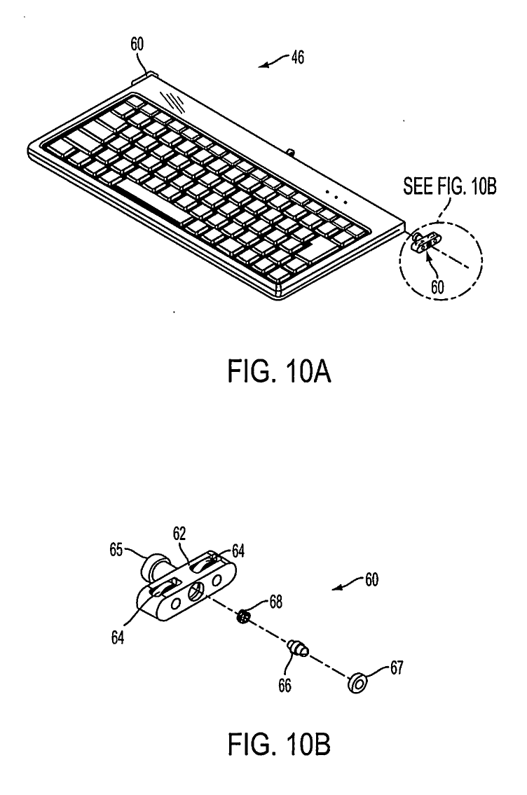

Each roller assembly 60 can comprise, for example, a body 62, and two rollers 64 mounted for rotation the body 62, as shown in FIGS. 10A and 10B. Each roller assembly 60 can be mounted via a first pin 65. The first pin 65 can securely engage the keyboard 46 by, for example, an interference, i.e., friction, fit. The body 62 of the roller assembly 60 can be coupled to, and configured to rotate about the first pin 65 using a second pin 66 that engages the first pin 65 by an interference fit or other suitable means. The body 62 can be held on the first and second pins 65, 66 by a ring 67 that is fixed to the body by an interference fit or other suitable means. A spring 68 disposed around the second pin 66 can urge the body 62 inwardly, against the first pin 65, while permitting a relatively small amount of lateral movement between the body 62 and the first pin 65. A stop 71 can be mounted on each of the brackets 54, proximate the forward end thereof, as shown in FIG. 11, to limit the forward movement of the rollers 60, which in turn limits the forward movement of the keyboard 46 and thereby prevents the keyboard 46 from being completely removed from the housing 44 of the keyboard module 12. Rollers 72 can be mounted for rotation on the lower portion 52 of the housing 44, to further support the keyboard 46 as the keyboard 46 moves out of the housing 44.

Details of the roller assemblies 60 are disclosed for exemplary purposes only. The keyboard 46 can be mounted for movement in relation to the remainder of the keyboard module 12 using other means in alternative embodiments.

The keyboard module 12 can be equipped with springs 76 that bias the keyboard toward its deployed position, as shown in FIGS. 7-9 and 11. The springs 76 can be mounted on the lower portion 52 of the housing 44, using a suitable means such as tabs 78.

The keyboard module 12 can also be equipped with a restraint in the form of a clip 82 that holds the keyboard 46 in its retracted position, as shown in FIGS. 7-9 and 11. The clip 82 can be mounted on the lower portion 52 of the housing 44, using a suitable means such as a tab 83. The clip 82 can resiliently engage a projection 84 mounted on the back of the keyboard 46, so that friction between the projection 84 and the clip 82 holds the keyboard 46 in the retracted position. The clip 82 can be configured to disengage from the projection 84 when the user pushes the keyboard 46 rearward, past its stowed position, i.e., further into the housing 44, by a relatively short distance. The clip 82 can be mounted on the keyboard 46, and the projection 84 can be mounted on the housing 44 in alternative embodiments. The clip 82 can be configured as a latch, magnet, or other type of restraint in other alternative embodiments.

Upon release of the keyboard 46 from the clip 82, the springs 76 urge or extract the keyboard 46 out of the housing 44, toward its deployed position. Thus, the keyboard 46 can be moved from its retracted to its deployed position by a combination of spring force, and manual force exerted by the user.

As the keyboard 46 reaches its deployed position, the forward motion of the keyboard 46 is limited by the stops 71 so that the keyboard 46 does not completely exit the housing 44. Moreover, the keyboard 46 can pivot so that a forward end of the keyboard 46 drops downward and rests on the underlying surface of the desk, table, or other object on which the system 10 is resting. The keyboard 46, when fully deployed, can thereby assume an orientation that is favorable for typing. Alternative embodiments of the system 10 can be configured without the keyboard module (12).

What is claimed is:

1. A docking system for an electronic device having a display, the docking system comprising:
a housing;
a keyboard mounted on the housing and configured to move between a stowed position wherein substantially all the keyboard is located within the housing, and a deployed position wherein substantially all of the keyboard is located outside of the housing;
a speaker mounted on the housing; and
an arm configured to hold the electronic device, the arm being mounted on the housing so that the arm is capable of rotating about a first axis in relation to the housing to facilitate adjustment of a viewing angle of the display while the electronic device is held by the arm.

2. The docking system of claim 1, wherein the arm has a first portion and a second portion, the second portion being pivotally connected to the housing, the first portion being mounted on the second portion so that the first portion can rotate in relation to the second portion about a second axis to facilitate adjustment of an orientation of the display when the electronic device is held by the arm.

3. The docking system of claim 2, wherein first portion is configured to rotate in relation to the second portion about the second axis to facilitate rotation of the display between portrait and landscape orientations.

4. The docking system of claim 2, further comprising:
a connector mounted on the first portion of the arm and configured to mate with a dock connector port of the electronic device; and
an electronics module communicatively coupled to the connector, the speaker, and the keyboard.

5. The docking system of claim 2, wherein the arm further comprises a third portion capable of being mounted on the first portion of the arm, wherein the third portion of the arm is configured to grasp the electronic device.

6. The docking system of claim 5, wherein the third portion of the arm is configured to grasp the electronic device when the electronic device has a first set of external dimensions; and
the arm further comprises a fourth portion configured to be mounted on the first portion of the arm on an interchangeable basis with the third portion, the fourth portion being further configured to grasp the electronic device when the electronic device has a second set of external dimensions.

7. The system of claim 4, wherein the electronics module facilitates communication between the keyboard and the electronic device by way of the connector.

8. The system of claim 4, wherein the electronics module is configured to transmit and receive analog and digital information and to receive power on a simultaneous basis.

9. The system of claim 4, wherein the electronics module further comprises an amplifier operable to generate an output that drives the speaker based on an input from the electronic device.

10. The system of claim 1, wherein: the keyboard module further comprises a restraint mounted on one of the keyboard and the housing, and a projection mounted on the other of the keyboard and the housing; the restraint is configured to securely grasp the projection when the keyboard is in the stowed position; and the restraint is configured to release the projection when the keyboard is moved past the stowed position.

11. The system of claim 1, further comprising a spring operable to bias the keyboard toward the deployed position.

12. The system of claim 4, further comprising an input module mounted on the housing and communicatively coupled to the electronics module, the input module comprising at least one of: a synchronization port; an auxiliary-input port; a port configured to receive electric power; and a high-definition multimedia interface port.

13. A docking system for an electronic device, comprising:
a housing;
an arm configured to hold the electronic device and comprising a first portion, a second portion, and a third portion, wherein:
an end of the second portion is pivotally coupled to the housing so that the second portion is capable of rotating in relation to the housing about a first axis extending in a first direction substantially perpendicular to a lengthwise direction of the second portion;
the first portion is mounted on the second portion so that the first portion is capable of rotating in relation to the second portion about a second axis extending in a second direction substantially perpendicular to the lengthwise direction of the second portion; and
the third portion is configured to be removably mounted on the first portion and to securely grasp the electronic device; and
a connector mounted on the first portion of the arm and configured to mate with a dock connector port of the electronic device.

14. The docking system of claim 13, wherein the third portion of the arm is configured to grasp the electronic device when the electronic device has a first set of external dimensions; and the arm further comprises a fourth portion configured to be mounted on the first portion of the arm on an interchangeable basis with the third portion, the fourth portion being further configured to grasp the electronic device when the electronic device has a second set of external dimensions.

15. The docking system of claim 13, further comprising a keyboard mounted on a first portion of the housing and configured to move into and out of the first portion of the housing, wherein the keyboard is communicatively coupled to the connector.

16. The docking system of claim 15, further comprising a speaker mounted on a second portion of the housing, and an amplifier communicatively coupled to the speaker and the connector.

17. A docking system for an electronic device having a display, the docking system comprising:
a housing;
a keyboard mounted on the housing and configured to move between a stowed position wherein substantially all the keyboard is located within the housing, and a deployed position wherein substantially all of the keyboard is located outside of the housing;
a speaker mounted on the housing;
an arm mounted on the housing, the arm being configured to hold the electronic device and to articulate in relation to the housing so that a viewing angle and a viewing orientation of the display can be adjusted while the electronic device is held by the arm;
a connector mounted on the arm and communicatively coupled to the keyboard and the speaker, the connector being configured to mate with a dock connector port of the electronic device.

18. The docking system of claim 17, wherein:
the arm has a first and a second portion;
the second portion is pivotally connected to the housing so that the arm is capable of rotating about a first axis in relation to the housing to facilitate adjustment of the viewing angle of the display; and
the first portion is mounted on the second portion so that the first portion can rotate in relation to the second portion about a second axis to facilitate adjustment of the viewing orientation of the display.

19. The docking system of claim 18, wherein the arm further comprises a third portion capable of being mounted on the first portion of the arm, wherein the third portion is configured to grasp the electronic device.

20. The docking system of claim 19, wherein the third portion of the arm is configured to grasp the electronic device when the electronic device has a first set of external dimensions; and the arm further comprises a fourth portion configured to be mounted on the first portion of the arm on an interchangeable basis with the third portion, the fourth portion being further configured to grasp the electronic device when the electronic device has a second set of external dimensions.
